(19) United States
(12) Patent Application Publication
(10) Pub. No.: US 2015/0016066 A1
(43) Pub. Date: Jan. 15, 2015

(54) CIRCUIT MODULE AND METHOD OF PRODUCING THE SAME

(71) Applicant: Taiyo Yuden Co., Ltd., Tokyo (JP)

(72) Inventors: Masaya SHIMAMURA, Tokyo (JP); Eiji MUGIYA, Tokyo (JP); Kenzo KITAZAKI, Tokyo (JP); Takehiko KAI, Tokyo (JP); Masafumi Imai, Tokyo (JP); Atsushi ITO, Tokyo (JP)

(73) Assignee: Taiyo Yuden Co., Ltd., Tokyo (JP)

(21) Appl. No.: 14/192,559

(22) Filed: Feb. 27, 2014

(30) Foreign Application Priority Data
Jul. 10, 2013 (JP) 2013-144579

(51) Int. Cl. H05K 9/00; H05K 3/28; H05K 5/06; H05K 3/22

(52) U.S. Cl. CPC H05K 9/0007; H05K 3/22; H05K 3/285; H05K 5/065
USPC 361/728; 29/841

(57) ABSTRACT

A circuit module includes a wiring substrate, an electronic component, a sealing layer, and a conductive shield. The wiring substrate has a mount surface. The electronic component is mounted on the mount surface. The sealing layer is formed of an insulating material, covers the electronic component, and has a first surface and a second surface, the first surface being opposite to the mount surface and having a first sealing area and a second sealing area, the second sealing area projecting from the first sealing area to an opposite side of the mount surface, the second surface being connected to the mount surface and the first surface. The conductive shield covers at least the second surface and the first sealing area of the first surface.

### CROSS-REFERENCE TO RELATED APPLICATION

This application claims the benefit under 35 U.S.C. §119 of Japanese Patent Application No. 2013-144579, filed Jul. 10, 2013, which is hereby incorporated by reference in its entirety.

### BACKGROUND OF THE INVENTION

The present disclosure relates to a circuit module having an electromagnetic shielding function and a method of producing the circuit module.

A circuit module that has a substrate on which a plurality of electronic components are mounted and is installed in various electronic apparatuses has been known. In general, such a circuit module employs a configuration that has an electromagnetic shielding function to prevent an electromagnetic wave from leaking to the outside of the module and entering from the outside.

In recent years, electronic components mounted in a circuit module are diversified while the circuit module is expected to be lower in height. For example, in the case where the entire circuit module is to be made as thin as possible, an electronic component having a relatively large height comes close to an electromagnetic shield. As a result, a parasitic capacitance is generated between the electronic component and the electromagnetic shield with a sealing resin being a dielectric disposed therebetween, thereby causing a problem in the operation of the electronic component in some cases.

As a configuration that prevents the parasitic capacitance between the electronic component and the electromagnetic shield from being generated, for example, Japanese Patent Application Laid-open No. 2012-009611 discloses a circuit module in which an electromagnetic shield film provided on an electronic component having a large height is opened. Furthermore, Japanese Patent Application Laid-open No. 2002-190690 discloses a circuit module configured such that a mount component having a large height penetrates an electromagnetic shield formed of a metal case.

### BRIEF SUMMARY

In the configuration described in Japanese Patent Application Laid-open No. 2012-009611, however, it is difficult to selectively remove only a part of the electromagnetic shield film. For example, in the case where the electromagnetic shield film is intended to be removed by laser irradiation, because an absorption coefficient of a laser beam of an electromagnetic shield film being a conductor is different from that of a sealing resin including an insulating resin, the sealing resin is easily burned off and the electronic component located immediately below the removal part is damaged in some cases if the intensity of the laser beam is set to be an intensity corresponding to the removal of the electromagnetic shield film. Meanwhile, a method of physically removing only a part of the electromagnetic shield film by polishing or the like has a problem of productivity.

On the other hand, in the configuration described in Japanese Patent Application Laid-open No. 2002-190690, there is a need to prepare a metal case having an opened portion through which the electronic component passes, thereby causing a problem of an increase in cost or the number of processes.

In view of the circumstances as described above, it is desirable to provide a circuit module capable of reducing electrical influence between the electromagnetic shield and the electronic component and a method of producing the circuit module.

According to an embodiment of the present disclosure, there is provided a circuit module including a wiring substrate, an electronic component, a sealing layer, and a conductive shield.

The wiring substrate has a mount surface.

The electronic component is mounted on the mount surface.

The sealing layer is formed of an insulating material, covers the electronic component, and has a first surface and a second surface, the first surface being opposite to the mount surface and having a first sealing area and a second sealing area, the second sealing area projecting from the first sealing area to an opposite side of the mount surface, the second surface being connected to the mount surface and the first surface.

The conductive shield covers at least the second surface and the first sealing area of the first surface.

According to an embodiment of the present disclosure, there is provided a method of producing a circuit module including preparing a wiring substrate having a mount surface on which an electronic component is mounted.

On the mount surface, a sealing layer that is formed of an insulating material, covers the electronic component, and has a first surface and a second surface is formed, the first surface being opposite to the mount surface and having a first sealing area and a second sealing area, the second sealing area projecting from the first sealing area to an opposite side of the mount surface, the second surface being connected to the mount surface and the first surface.

A conductive shield covering an outer surface of the sealing layer is formed.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a perspective view showing a circuit module according to a first embodiment of the present disclosure;

FIG. 2 is a plan view of the circuit module;

FIG. 3 is a plan view of a wiring substrate on which an electronic component is mounted in the circuit module;

FIG. 4 is a cross-sectional view taken along the direction of the line [A]-[A] of FIG. 2;

FIG. 5 is a plan view showing a state where a conductive shield is removed from the wiring substrate of the circuit module, so that a sealing layer is exposed;

FIGS. 6A and 6B are schematic cross-sectional views for explaining a method of producing the circuit module;

FIGS. 7A and 7B are schematic cross-sectional views for explaining a method of producing the circuit module;

FIGS. 8A and 8B are schematic cross-sectional views for explaining a method of producing the circuit module;

FIG. 9 is a cross-sectional view showing a circuit module according to a comparative example of the first embodiment of the present disclosure;

FIG. 10 is a cross-sectional view showing a circuit module according to a second embodiment of the present disclosure;

FIG. 11 is a cross-sectional view showing a circuit module according to a third embodiment of the present disclosure;

FIG. 12 is a cross-sectional view showing a circuit module according to a modified example of the third embodiment of the present disclosure;

FIG. 13 is a cross-sectional view showing a circuit module according to a fourth embodiment of the present disclosure; and

FIG. 14 is a plan view of the circuit module.

### DETAILED DESCRIPTION

A circuit module according to an embodiment of the present disclosure includes a wiring substrate, an electronic component, a sealing layer, and a conductive shield.

The wiring substrate has a mount surface.

The electronic component is mounted on the mount surface.

The sealing layer is formed of an insulating material, covers the electronic component, and has a first surface and a second surface, the first surface being opposite to the mount surface and having a first sealing area and a second sealing area, the second sealing area projecting from the first sealing area to an opposite side of the mount surface, the second surface being connected to the mount surface and the first surface.

The conductive shield covers at least the second surface and the first sealing area of the first surface.

In the circuit module, a partial area of a sealing layer formed of a dielectric (insulator) is formed to have a thickness larger than other areas. Accordingly, it is possible to reduce the parasitic capacitance between the electronic component and the conductive shield or to prevent the parasitic capacitance from being generated. Therefore, it is possible to prevent a problem in the operation of each electronic component mounted in the circuit module from occurring, and to cause the conductive shield to sufficiently exert the electromagnetic shielding function.

Moreover, the second sealing area may be provided opposite to the electronic component.

Owing to the second sealing area, even in the case where the entire circuit module is reduced in size, it is possible to ensure enough space between the electronic component and the conductive shield. Accordingly, it is possible to reduce the parasitic capacitance between the electronic component and the conductive shield. Therefore, it is possible to stably maintain the electromagnetic shielding function of the conductive shield and to prevent the problem of the electronic component from occurring.

The conductive shield may further cover the second sealing area of the first surface.

Accordingly, because the conductive shield covers the first and second surfaces (outer surface) of the sealing layer, it is possible to exert the electromagnetic shielding function more effectively.

Moreover, the conductive shield may have a first shield portion having a first shield area and a second shield area, the first shield portion covering the first surface, the first shield area being formed on the first sealing area with a first thickness, the second shield area being formed on the second sealing area with a second thickness smaller than the first thickness, and a second shield portion covering the second surface, the second shield portion having a second shield portion connected to the mount surface.

Accordingly, it is possible to make the surface of the first shield portion substantially flat, for example.

The conductive shield may have an opening exposing the second sealing area.

Accordingly, it is possible to achieve a configuration in which the conductive shield is not formed in an area in which the conductive shield can affect the electronic component, and to reduce electrical influence on the electronic component due to the conductive shield.

Moreover, the opening may have a bottom surface exposing the second sealing area, and the conductive shield may further have an edge portion formed around the exposed second sealing area, the edge portion being exposed from the bottom surface of the opening.

With such a configuration, it is possible to form the opening to be larger than the second sealing area in a plan view, and to reliably open the second sealing layer.

The wiring substrate may include a ground terminal electrically connected to the conductive shield.

Accordingly, it is possible to maintain the conductive shield at a ground potential, and to cause the conductive shield to exert the electromagnetic shielding function more stably.

Moreover, a method of producing a circuit module according to an embodiment of the present disclosure includes preparing a wiring substrate having a mount surface on which an electronic component is mounted.

On the mount surface, a sealing layer that is formed of an insulating material, covers the electronic component, and has a first surface and a second surface is formed, the first surface being opposite to the mount surface and having a first sealing area and a second sealing area, the second sealing area projecting from the first sealing area to an opposite side of the mount surface, the second surface being connected to the mount surface and the first surface.

A conductive shield covering an outer surface of the sealing layer is formed.

Moreover, the forming of the sealing layer may include forming a first sealing layer covering the electronic component, disposing, on the first sealing layer, a mask having an opening in an area corresponding to the second sealing area, and forming, on the first sealing layer, a second sealing layer via the opening of the mask.

Accordingly, it is possible to form the sealing layer by laminating the first and second sealing layers without an etching process or a patterning process such as laser processing. Therefore, it is possible to easily form the sealing layer while suppressing influence on the wiring substrate or the electronic component.

Furthermore, the method of producing a circuit module may further include removing the conductive shield on the second sealing area.

According to the producing method, because a portion corresponding to the second sealing area of the sealing layer projects to the opposite side of the mount surface, it is possible to selectively expose only the second sealing area by removing the entire upper surface of the conductive shield by polishing or the like. Therefore, with no complicated process, it is possible to form the opening having a configuration in which the second sealing area is exposed in the conductive shield.

Hereinafter, embodiments according to the present disclosure will be described with reference to the drawings.

### First Embodiment

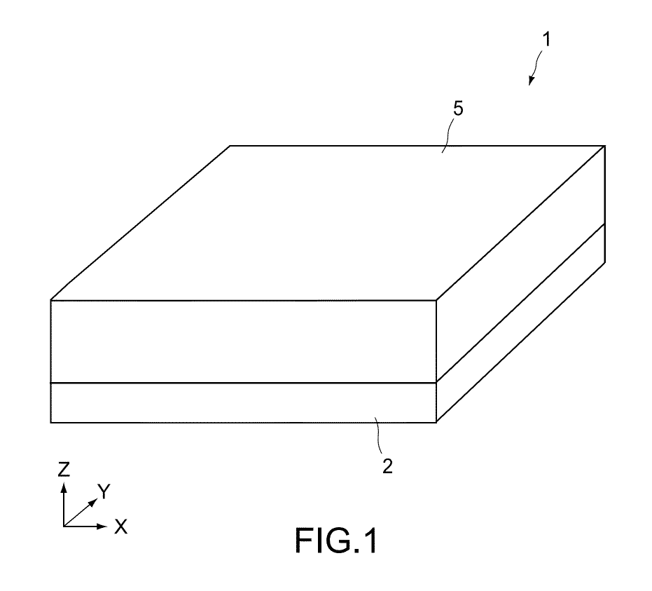

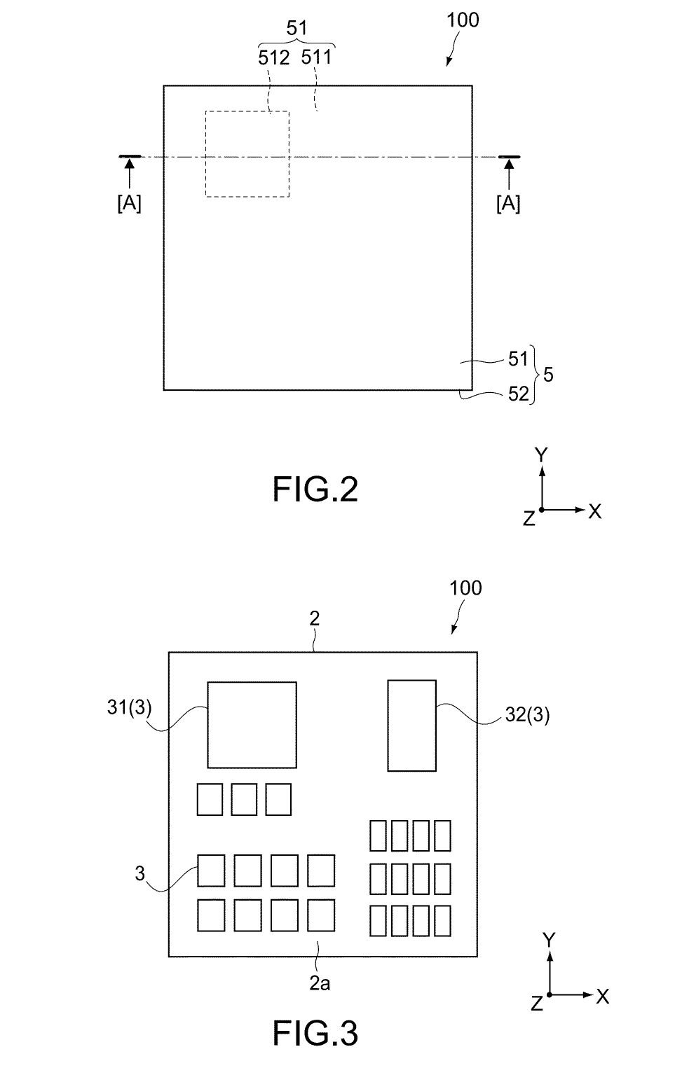

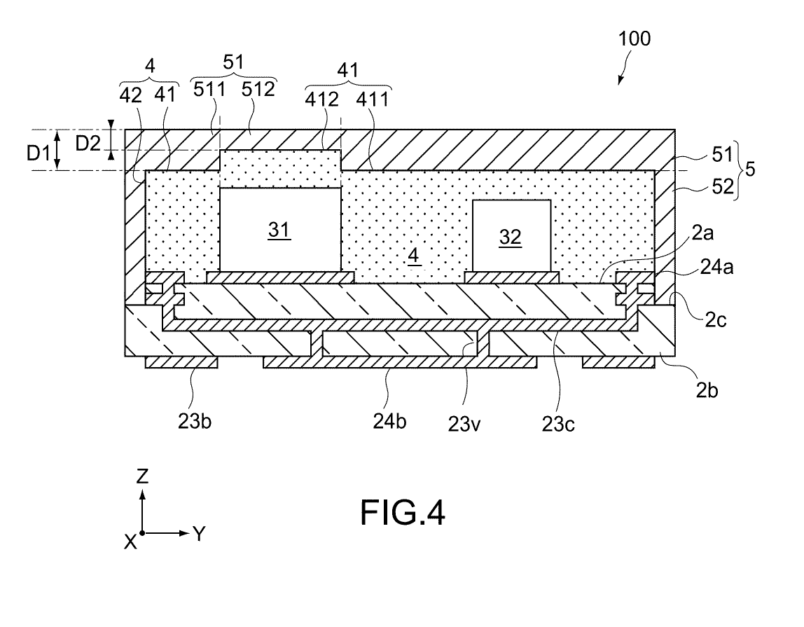

FIGS. 1 to 4 are each a diagram showing a circuit module according to an embodiment of the present disclosure. FIG. 1 is a perspective view, FIG. 2 is a plan view, FIG. 3 is a plan view of a wiring substrate, and FIG. 4 is a cross-sectional view taken along the direction of the line [A]-[A] of FIG. 2.

It should be noted that in each figure, X-, Y-, and Z-axes represent triaxial directions orthogonal to each other, and the Z-axis direction corresponds to the thickness direction of the circuit module. It should be noted that the configuration of each portion is exaggeratingly shown in order to facilitate understanding, and the sizes of the members or the ratios of the sizes of the members do not necessarily correspond to each other in the figures.

(Configuration of Circuit Module)

A circuit module 100 according to this embodiment includes a wiring substrate 2, an electronic component 3, a sealing layer 4, and a conductive shield 5.

The circuit module 100 is configured to have a substantially rectangular parallelepiped shape as a whole. The size of the circuit module 100 is not particularly limited. For example, the circuit module 100 is configured to have a length of 10 to 50 mm along the X-axis direction and a length of 10 to 50 mm along the Y-axis direction. In this embodiment, the circuit module 100 is configured to have a substantially square shape having a side length of about 35 mm. Also the thickness of the circuit module 100 is not particularly limited. For example, the circuit module 100 is configured to have a thickness of 1 to 3 mm. In this embodiment, the circuit module 100 is configured to have a thickness of about 2 mm.

In the circuit module 100, a plurality of electronic components 3 are disposed on the wiring substrate 2, and the sealing layer 4 and the conductive shield 5 are formed so as to cover them. Hereinafter, the configuration of the respective portions of the circuit module 100 will be described.

(Wiring Substrate)

The wiring substrate 2 has a mount surface 2a formed to have a substantially square shape and the same size as the entire circuit module 100, for example, and a terminal surface 2b formed on the opposite side of the mount surface 2a. The wiring substrate 2 includes a glass epoxy multilayer wiring substrate having a thickness of about 0.4 mm, for example. The material forming the insulating layer of the wiring substrate 2 is not limited to the above-described glass epoxy material, and an insulating ceramic material can be employed, for example.

The wiring layer of the wiring substrate 2 typically includes a copper foil, and is disposed on the front surface, rear surface, and inner layer of the wiring substrate 2. The wiring layer is subjected to patterning into a predetermined shape to form an upper layer wiring portion 23a disposed on the mount surface 2a, a lower layer wiring portion 23b disposed on the terminal surface 2b, and an inner layer wiring portion 23c disposed therebetween. The upper layer wiring portion 23a has a land portion on which the electronic component 3 is mounted, and the lower layer wiring portion 23b includes an external connection terminal connected to a control substrate (illustration omitted) of the electronic apparatus on which the circuit module 100 is mounted. The wiring portions of the layers are electrically connected to each other via a via conductor 23v.

Moreover, the above-mentioned wiring layer includes a first ground (GND) terminal 24a and a second GND terminal 24b, which are connected to a GND potential. The first GND terminal 24a is disposed adjacent to an uneven surface 2c formed around the upper surface of the wiring substrate 2, and is connected to the inner surface of the conductive shield 5 (second shield portion 52) disposed on the uneven surface 2c. The first GND terminal 24a may be formed as a part of the upper layer wiring portion 23a, or a part of the inner layer wiring portion 23c.

The second GND terminal 24b is connected to the first GND terminal 24a via the inner layer wiring portion 23c. The second GND terminal 24b is formed as a part of the lower layer wiring portion 23b, and is connected to a ground wiring of the above-mentioned control substrate.

(Electronic Component)

The electronic component 3 is mounted on the mount surface 2a. As shown in FIG. 3, in this embodiment, the electronic component 3 includes a plurality of electronic components. Examples of the plurality of electronic components typically include various components such as an integrated circuit (IC), a capacitor, an inductor, a resistor, a crystal oscillator, a duplexer, a filter, and a power amplifier. These components include components having a casing formed of a conductor such as a metal conductor. Moreover, these components include components that generate an electromagnetic wave around them during operation or components liable to be affected by the electromagnetic wave.

FIG. 4 shows, as an example, an electronic component 31 and an electronic component 32 having a height lower than that of the electronic component 31. Here, “the height of the electronic component” is a height from the mount surface 2a along the Z-axis direction.

The plurality of electronic components 3 are typically mounted on the mount surface 2a by soldering, an adhesive, a bonding wire, or the like.

(Sealing Layer)

The sealing layer 4 includes an insulating material and is formed on the mount surface 2a so as to cover the plurality of electronic components 31 and 32. The sealing layer 4 includes an insulating resin such as an epoxy resin to which silica or alumina is added. The method of forming the sealing layer 4 is not particularly limited. For example, the sealing layer 4 may be formed by a molding method or a screen printing method, as will be described later.

The sealing layer 4 has a first surface 41 that is opposed to the mount surface 2a and the second surface 42 connected to the mount surface 2a and the first surface 41, and is configured to cover the electronic components 31 and 32 (electronic component 3). The first surface 41 is configured as a main surface (upper surface) of the sealing layer 4, and the second surface 42 is configured as all side surfaces or a peripheral surface of the sealing layer 4.

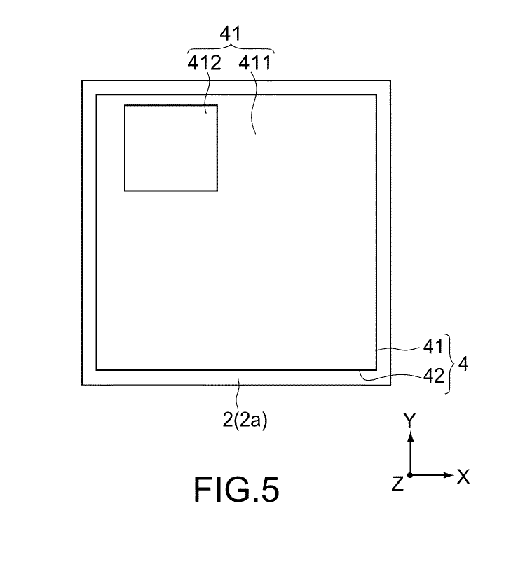

FIG. 5 is a plan view showing a state where the conductive shield 5 is removed from the wiring substrate 2 to expose the sealing layer 4. As shown in FIG. 5, the first surface 41 has a first sealing area 411 and a second sealing area 412.

In this embodiment, the first sealing area 411 forms an area of the first surface 41, which is not opposed to the electronic component 31. In this embodiment, the first sealing area 411 forms a substantially flat surface, but the first sealing area 411 is not limited thereto.

The second sealing area 412 is configured to project from the first sealing area 411 to the opposite side of the mount surface 2a. Specifically, the second sealing area 412 is configured as a convex portion that projects upward in the Z-axis direction from the first sealing area 411. The height that the second sealing area 412 projects from the first sealing area 411 in the Z-axis direction is not particularly limited, and is about 100 to 300 μm, for example.

Moreover, in this embodiment, the second sealing area 412 is provided on the first surface 41 so as to be opposed to the electronic component 31. The shape of the second sealing area 412 is not particularly limited, and the second sealing area 412 is configured as an area having a substantially square shape about 0.3 μm on a side, as seen from the Z-axis direction, for example.

(Conductive Shield)

The conductive shield 5 is formed on the sealing layer 4 and is configured to cover at least the second surface 42 and the first sealing area 411 of the first surface 41. In this embodiment, the conductive shield 5 further covers the second sealing area 412 of the first surface 41, and is configured to cover the entire outer surface (surface of the sealing layer 4, which includes the first surface 41 and the second surface 42; the same shall apply hereinafter) of the sealing layer 4.

The conductive shield 5 has a first shield portion 51 and the second shield portion 52. The first shield portion 51 is configured to cover the first surface 41 of the sealing layer 4 and include the upper surface of the conductive shield 5. The second shield portion 52 is configured to cover the second surface 42 and include all side surfaces of the conductive shield 5.

The first shield portion 51 has a first shield area 511 and a second shield area 512. With reference to FIG. 4, the first shield area 511 is formed on the first sealing area 411 and is configured to have a first thickness D1. On the other hand, the second shield area 512 is formed on the second sealing area 412 and is configured to have a second thickness D2 smaller than the first thickness D1. The thickness D1 and the thickness D2 are 150 to 450 μm and 50 to 150 μm, respectively, for example, but are not limited thereto as long as a desired shielding effect can be achieved. Specifically, the outer surface of the first shield portion 51 is configured to be a substantially flat surface. On the other hand, on the inner surface of the first shield portion 51, a concave portion corresponding to the second shield area 512 is formed.

Moreover, the second shield portion 52 is configured to reach the uneven surface 2c of the wiring substrate 2, and is electrically connected to the first GND terminal 24a. Accordingly, it is possible to maintain the electromagnetic shielding function of the conductive shield 5 more stably. The thickness of the second shield portion 52 is, for example, 50 to 250 μm, but is not particularly limited as long as a desired shielding effect can be achieved.

The conductive shield 5 includes a cured conductive resin material filled on the outer surface of the sealing layer 4. More specifically, an epoxy resin to which conductive particles of Ag, Cu, and the like are added is adopted. Alternatively, the conductive shield 5 may be a plating film or a sputtering film deposited on the outer surface of the sealing layer 4.

(Method of Producing Circuit Module)

Next, a method of producing the circuit module 100 according to this embodiment will be described.

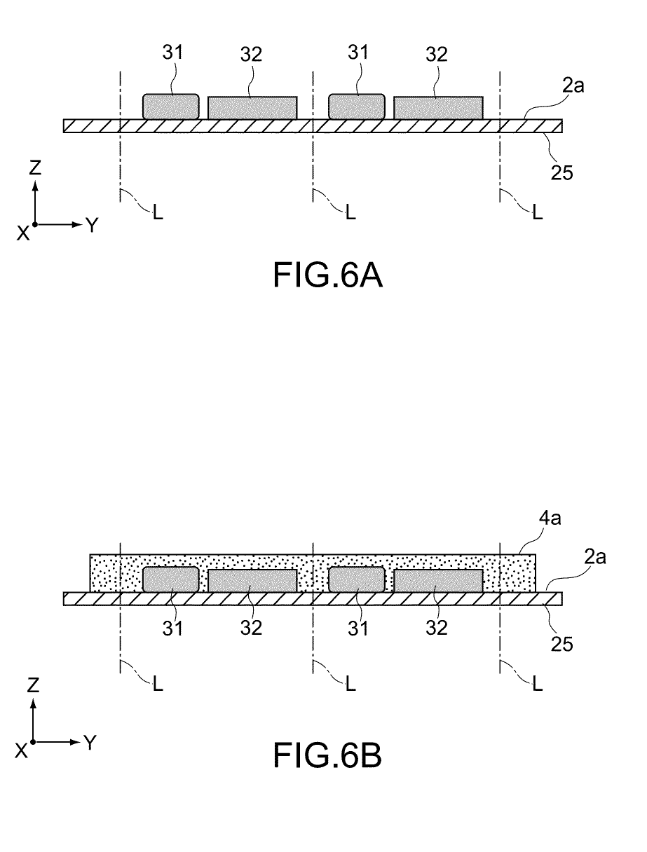

FIGS. 6 to 8 are each a cross-sectional view of a main portion seen from the X-axis direction for explaining a method of producing the circuit module 100. The method of producing the circuit module according to this embodiment includes a process of preparing an aggregate substrate, a process of mounting an electronic component, a process of forming a sealing layer, a half-cut process, a process of forming a conductive shield, and a cutting process. Hereinafter, each process will be described.

(Process of Preparing Aggregate Substrate)

FIG. 6A is a diagram for explaining the process of preparing an aggregate substrate and a process of mounting the electronic component 3 (31 and 32). With reference to FIG. 6A, an aggregate substrate 25 includes a substrate with a large area on which a plurality of wiring substrates 2 are attached. FIG. 6A shows separation lines L dividing the plurality of wiring substrates 2. The separation line L may be a virtual line or may be actually drawn on the aggregate substrate 25 by printing or the like.

On the aggregate substrate 25, the conductive shield 5 is finally formed through each process to be described later. In the cutting process being the last process, the aggregate substrate 25 is cut (full-cut) along the separation line L to produce a plurality of circuit modules 100. Moreover, although not shown, in the aggregate substrate 25, predetermined wiring patterns (11, 23a, 23b, 23c, 23v, 24a, 24b, and the like) are formed for each area forming the wiring substrate 2.

It should be noted that in the example shown in FIG. 6A, an example in which four wiring substrates 2 are cut from the aggregate substrate 25 is shown. The number of wiring substrates 2 to be cut is not particularly limited. For example, in the case where a substrate configured to have a substantially square shape of about 150 mm square is used as the aggregate substrate 25, four wiring substrates 2 of about 35 mm square are arranged in the X-axis direction and the Y-axis direction, i.e., sixteen wiring substrates 2 are arranged. Moreover, as the aggregate substrate 25, a substrate having a rectangular shape about 100 to 200 mm on a side is typically adopted.

(Process of Mounting Electronic Component)

Subsequently with reference to FIG. 6A, the process of mounting an electronic component will be described. FIG. 6A shows a state where the electronic components 31 and 32 are disposed on the aggregate substrate 25 (wiring substrate 2).

In this process, the plurality of electronic components 31 and 32 are mounted on the mount surface 2a. As the method of mounting the electronic components 31 and 32, a reflow process is adopted, for example. Specifically, first, a soldering paste is applied to a predetermined land portion on the mount surface 2a by a screen printing method or the like. Next, the plurality of electronic components 31 and 32 are mounted on the predetermined land portion via the soldering paste. After that, the aggregate substrate 25 on which the electronic components 31 and 32 are mounted is loaded into a reflow furnace, and the electronic components 31 and 32 are electrically and mechanically bonded to the mount surface 2a by performing a reflow process on the soldering paste.

(Process of Forming Sealing Layer)

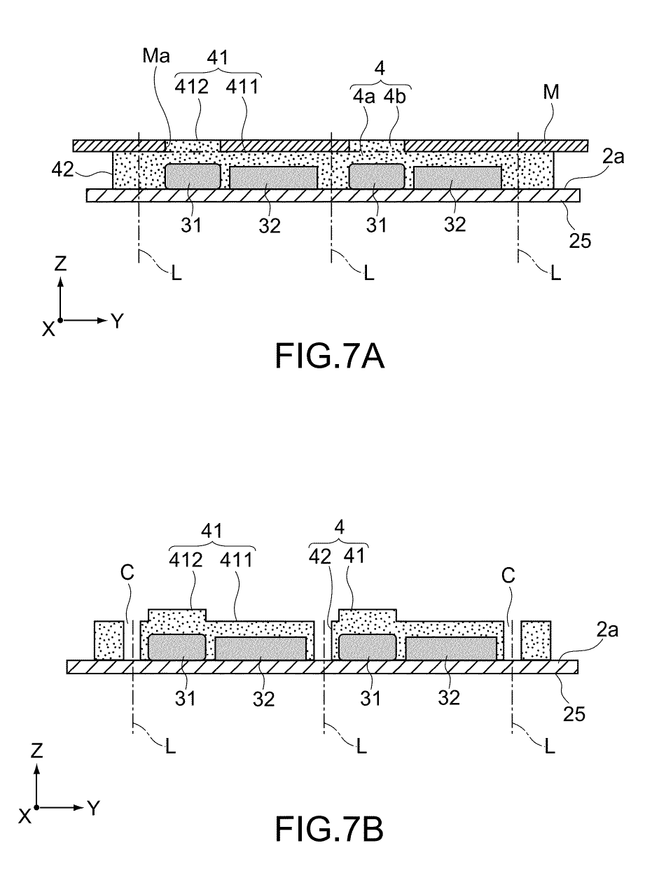

FIGS. 6B and 7A are each a diagram for explaining the process of forming the sealing layer 4. In this embodiment, the process of forming the sealing layer 4 includes a process of forming a first sealing layer 4a, a process of disposing a mask, and a process of forming a second sealing layer 4b.

FIG. 6B shows a state where the first sealing layer 4a is formed on the mount surface 2a. The first sealing layer 4a is formed on the mount surface 2a of the aggregate substrate 25 so as to cover the electronic components 31 and 32. The method of forming the first sealing layer 4a is not particularly limited, and a molding method using a mold, a potting molding method using no mold, or the like can be applied, for example. Moreover, after a liquid or paste sealing resin material is applied to the mount surface 2a by a spin coating method or a screen printing method, the resultant product may be cured by heat treatment.

Next, with reference to FIG. 7A, a mask M is disposed on the first sealing layer 4a. The mask M has an opening Ma in an area corresponding to the second sealing area 412. Accordingly, a part of the surface of the first sealing layer 4a is exposed via the opening Ma. As the mask M, a metal mask formed of metal may be applied or a resist mask formed of a resin or the like may be applied.

Subsequently with reference to FIG. 7A, the second sealing layer 4b is formed on the first sealing layer 4a via the opening of the mask M. The method of forming the second sealing layer 4b is not particularly limited. For example, a liquid or paste sealing resin material may be applied to the first sealing layer 4a via the mask M by a screen printing method or the like, and the resultant product may be cured by heat treatment. Moreover, the second sealing layer 4b may include the same material as the first sealing layer 4a, or include a material different from that of the first sealing layer 4a.

Accordingly, as shown in FIG. 7A, the sealing layer 4 including the first surface 41 and the second surface 42 is formed on the mount surface 2a. The first surface 41 has the first sealing area 411 and the second sealing area 412 projecting from the first sealing area 411 to an opposite side of the mount surface 2a, the first surface 41 being opposite to the mount surface 2a. The second surface 42 is connected to the mount surface 2a and the first surface 41. The sealing layer 4 includes an insulating material and covers the electronic components 31 and 32.

(Half-Cut Process)

FIG. 7B is a diagram for explaining the half-cut process. In this process, cut grooves C are formed along the separation line L with a depth with which the cut grooves C reach the inside of the aggregate substrate 25 from the first surface 41 being the upper surface of the sealing layer 4 by a dicer, for example. The cut groove C forms the uneven surface 2c of the aggregate substrate 25 (wiring substrate 2). The depth of the cut groove C is not particularly limited. However, the cut groove C is formed to have a depth with which the first GND terminal 24a on the aggregate substrate 25 can be divided.

(Process of Forming Conductive Shield)

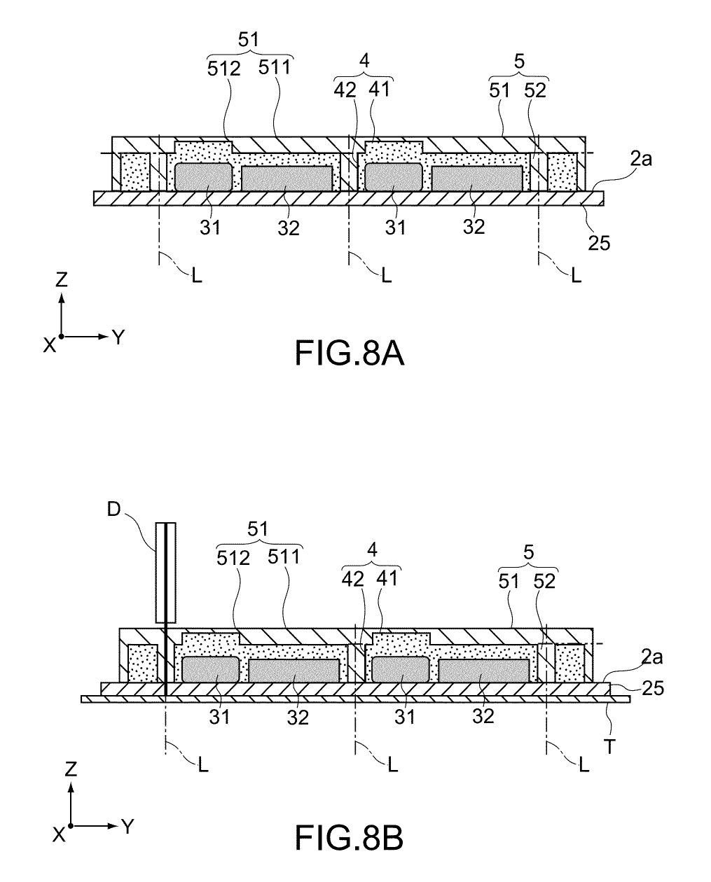

FIG. 8A is a diagram for explaining the process of forming the conductive shield 5. The conductive shield 5 is formed so as to cover the first surface 41 and the second surface 42 being the outer surfaces of the sealing layer 4. Accordingly, the first shield portion 51 covering the first surface 41 of the sealing layer 4 and the second shield portion 52 covering the second surface 42 are formed.

In this embodiment, the conductive shield 5 is formed by applying or filling a conductive resin or conductive paint to/on the surface of the sealing layer 4 and to/in the cut groove C. The method of forming the conductive shield 5 is not particularly limited, and a molding method using a mold, a potting molding method using no mold, or the like can be applied, for example. Moreover, after a liquid or paste sealing resin material is applied to the sealing layer 4 by a spin coating method or a screen printing method, the resultant product may be cured by heat treatment. Moreover, in order to improve the efficiency of filling the conductive resin in the cut groove C, the process may be performed in a vacuum atmosphere.

The conductive resin forming the second shield portion 52 is also filled in the cut groove C formed in the sealing layer 4, and thus is connected to the first GND terminal 24a on the wiring substrate 2 approaching the cut groove C. Accordingly, the second shield portion 52 and the first GND terminal 24a are electrically and mechanically connected to each other.

The forming of the conductive shield 5 may be performed by a vacuum deposition method such as a plating method and a sputtering method. In the plating method, by immersing the aggregate substrate 25 in a plating bath and depositing a plating film on the outer surface of the sealing layer 4 and the inner wall surface of the cut groove C, it is possible to form the conductive shield 5. In the sputtering method, by loading the aggregate substrate 25 into a vacuum chamber and sputtering a target including a conductive material to deposit a sputtering film on the outer surface of the sealing layer 4 and the inner wall surface of the cut groove C, it is possible to form the conductive shield 5.

(Cutting Process)

FIG. 8B is a diagram for explaining the cutting process. In this process, the aggregate substrate 25 is full-cut along the separation line L on a dicing tape T, and thus divided into a plurality of circuit modules 100. For the separation, as shown in FIG. 8A, a dicer D or the like is used. In this embodiment, because the conductive shield 5 is also filled in the cut groove C, the aggregate substrate 25 is separated along the separation line L so that the wiring substrate 2 and the conductive shield 5 have the same cut surface.

Accordingly, the circuit module 100 including the conductive shield 5 that covers the outer surface (the first surface 41 and the second surface 42) of the sealing layer 4 as shown in FIG. 4 and a part of the side surface of the wiring substrate 2 is prepared. Then, each of the full-cut circuit modules 100 is taken out by a picker or the like, and is mounted in a predetermined electronic apparatus or the like.

### Operation of this Embodiment

Through the above-mentioned processes, the circuit module 100 is produced. According to the method of producing the circuit module according to this embodiment, the second sealing area 412 of the sealing layer 4, which is provided opposed to the electronic component 31, is formed so as to project upward in the Z-axis direction. Accordingly, even in the case where the entire circuit module is reduced in size as much as possible while taking into account the thickness (height) of the electronic component 31 having a large thickness (height), it is possible to ensure enough space between the electronic component 31 and inner surface of the conductive shield 5 owing to the projected second sealing area 412. Therefore, it is possible to reduce the parasitic capacitance generated between the electronic component 31 and the conductive shield 5 while reducing the circuit module 100 in size. Accordingly, it is possible to sufficiently ensure the electromagnetic shielding function of the conductive shield 5 and to prevent the problem such as a malfunction of the electronic component 31 from occurring.

Here, in order to reduce the parasitic capacitance, a method of removing the conductive shield in the area on the electronic component 31 is proposed. However, if a partial area of the conductive shield is intended to be removed without consideration of the thickness of the sealing layer, the following problem occurs.

For example, as a method of removing a partial area of the conductive shield, a method of irradiating a laser beam from above the conductive shield to remove the conductive shield on the electronic component is proposed. However, in general, an absorption coefficient of a laser beam of the conductive shield formed of metal, a conductive resin, or the like is significantly different from that of the sealing layer formed of an insulating resin or the like. Specifically, in the case where a laser beam having an intensity with which the conductive shield can be removed is irradiated, the sealing layer is quickly burned off when the laser beam reaches the sealing layer.

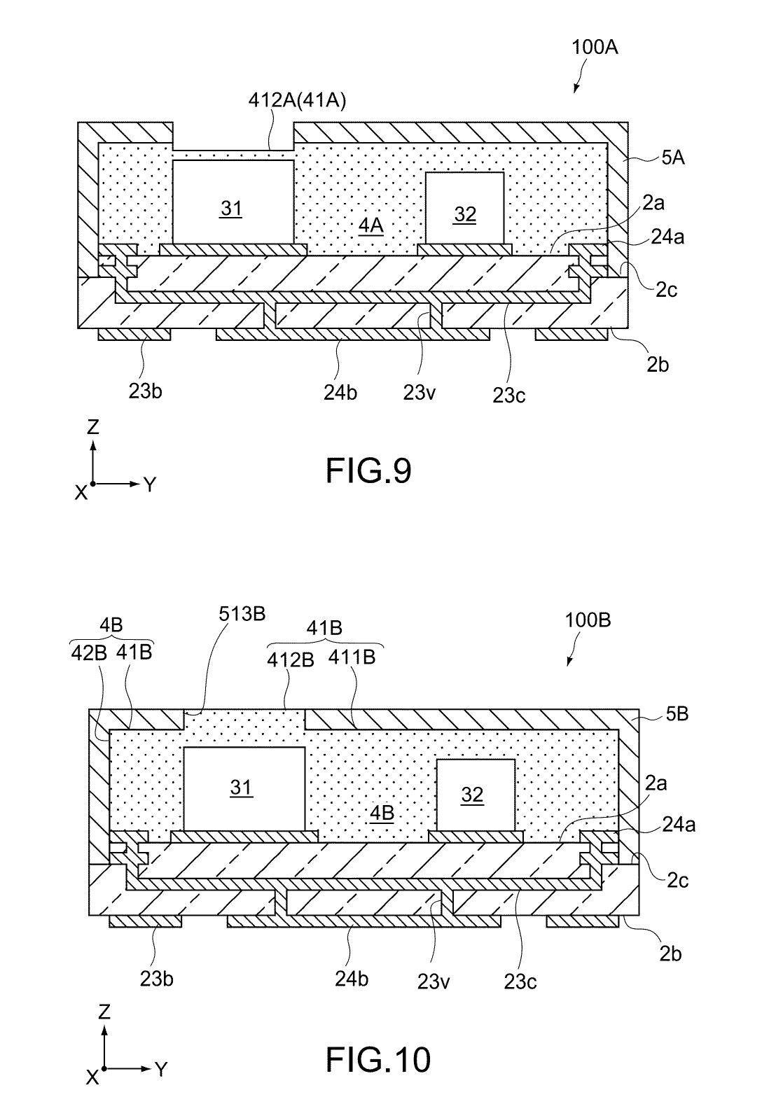

FIG. 9 is a schematic cross-sectional view showing the configuration of a circuit module 100A according to a comparative example of this embodiment, in which a part of the conductive shield is removed by irradiation of a laser beam. In this comparative example, although a conductive shield 5A in the area that is opposed to the electronic component 31 is removed, a concave portion 412A is formed on a surface 41A of the sealing layer 4, which corresponds to the area. The concave portion 412A is formed because a part of a sealing layer 4A is burned out when the conductive shield 5A is removed by irradiation of a laser beam. As described above, in the case where the method of removing the conductive shield with a laser beam is used, it is difficult to adjust the intensity of the laser beam, and the electronic component 31 located immediately below the sealing layer 4A may be damaged.

Alternatively, a method of removing only a partial area of the conductive shield by polishing or the like may also be used. However, the method involves polishing a very small area and thus has a problem of productivity. Moreover, in the case where the upper surface of the sealing layer is formed to be substantially flat, the entire upper surface of the sealing layer is exposed if the entire upper surface of the conductive shield is polished. Therefore, it is hard to achieve a desired electromagnetic shielding function.

In this regard, according to the producing method according to this embodiment, by laminating the second sealing layer 4b on the first sealing layer 4a having a substantially flat surface via the mask M, it is possible to easily form the sealing layer 4 having the second sealing area 412 that projects in the Z-axis direction. With such a method, it is possible to reduce the parasitic capacitance (capacitive coupling) between the electronic component 31 and the conductive shield 5 from being generated, and to produce the circuit module 100 without damaging the electronic component. Moreover, it is possible to avoid complicated processes and to maintain high productivity.

Furthermore, according to this embodiment, it is possible to stably ensure the electromagnetic shielding function of the conductive shield because the conductive shield covers the entire outer surface of the sealing layer.

Moreover, according to the producing method according to this embodiment, it is possible to form the conductive shield by a conductive paste or the like. Accordingly, it is possible to easily form the conductive shield and to reduce the increase in cost, as compared with the case where a lid member or the like formed of metal is used.

### Second Embodiment

FIG. 10 is a schematic cross-sectional view showing a circuit module according to a second embodiment of the present disclosure, which corresponds to the cross-sectional view shown in FIG. 4. Hereinafter, the configuration different from that of the first embodiment will be mainly described, and the same configuration as that according to the above-mentioned embodiment will be denoted by the same reference symbols and a description thereof will be omitted or simplified.

In a circuit module 100B according to this embodiment, a conductive shield 5B covers a second surface 42B of a sealing layer 4B and a first sealing area 411B of a first surface 41B, and does not cover a second sealing area 412B. Specifically, the conductive shield 5B has an opening 513B exposing the second sealing area 412B.

According to this embodiment, it is also possible to prevent the parasitic capacitance (capacitive coupling) between the electronic component 31 and the conductive shield 5B from being generated. Moreover, it is possible to regulate the thickness of the entire circuit module 100B, and to reduce the circuit module 100B in size.

Next, a method of producing the circuit module 100B having such a configuration will be described. The method of producing the circuit module 100B according to this embodiment further includes a process of removing the conductive shield on the second sealing area 412B by polishing in addition to the same processes as those in the first embodiment.

Specifically, the method of producing the circuit module according to this embodiment includes a process of preparing an aggregate substrate, a process of mounting an electronic component, a process of forming a sealing layer, a half-cut process, a process of forming a conductive shield, a process of removing a part of the conductive shield, and a cutting process.

In this embodiment, after the process of forming the conductive shield, the conductive shield is removed by polishing by a thickness corresponding to the thickness D2 shown in FIG. 4 prior to the cutting-process. The method of polishing is not particularly limited, and it is possible to polish the entire surface of the first shield portion of the conductive shield by dry polishing or the like. Accordingly, as shown in FIG. 10, it is possible to form the circuit module 100B having a configuration in which the upper surface is substantially flat.

Moreover, the first surface 41B of the sealing layer 4B according to this embodiment has the second sealing area 412B that projects upward in the Z-axis direction. Accordingly, it is possible to form the conductive resin on the first sealing area 411B with the thickness D1 and the conductive resin on the second sealing area 412B with the thickness D2 that is smaller than D1 when the conductive resin is applied or filled (see FIGS. 4 and 8A). Therefore, it is possible to easily form the opening 513B on the second sealing area 412B selectively so that the conductive resin on the first sealing area 411B has a predetermined thickness (D1-D2) by polishing the thickness D2 of the entire upper surface of the conductive shield.

Moreover, by polishing the entire upper surfaces of conductive shields of a plurality of circuit modules 100B prior to the cutting process, it is possible to form the conductive shields 5B of the plurality of circuit modules 100B at the same time. Accordingly, it is possible to maintain the productivity.

In addition, according to the method of producing the circuit module 100B according to this embodiment, as described in the first embodiment, there is no need to adopt laser processing when the conductive shield 5B is removed. Accordingly, it is possible to remove the conductive shield 5B while preventing the electronic component 31 from being damaged.

### Third Embodiment

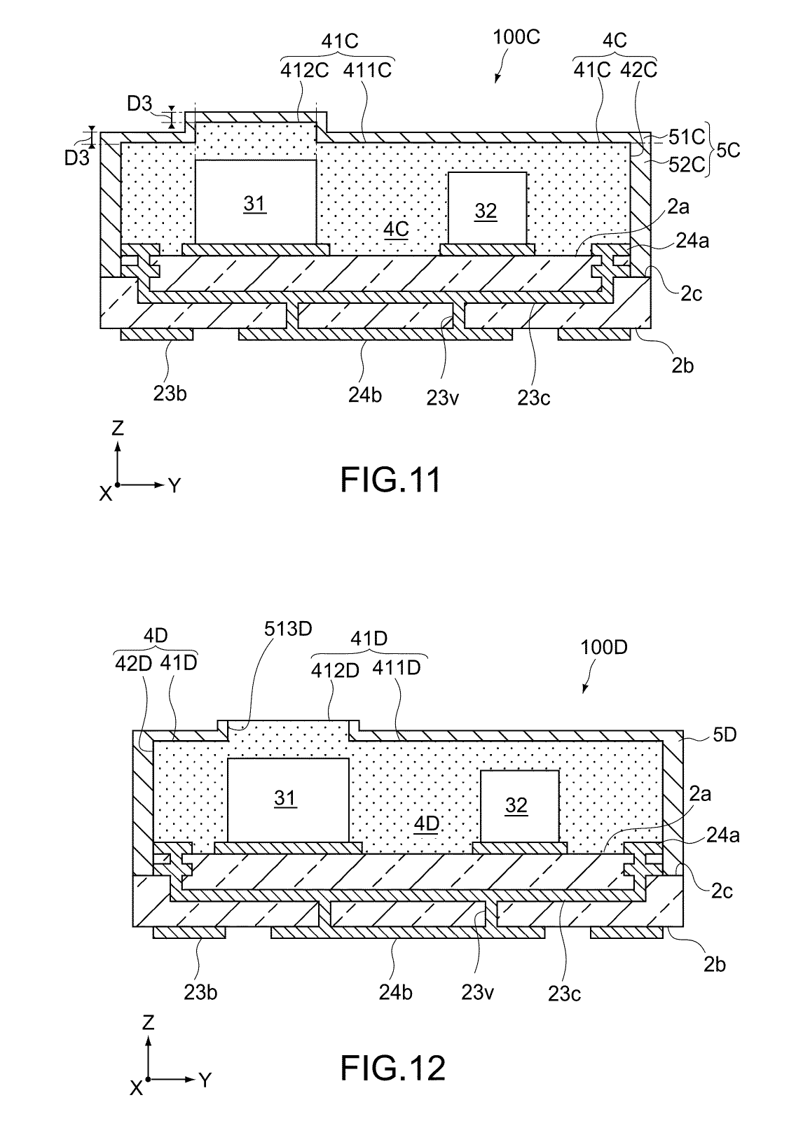

FIG. 11 is a schematic cross-sectional view showing a circuit module according to a third embodiment of the present disclosure, which corresponds to the cross-sectional view shown in FIG. 4. Hereinafter, the configuration different from that of the first embodiment will be mainly described, and the same configuration as that according to the above-mentioned embodiment will be denoted by the same reference symbols and a description thereof will be omitted or simplified.

In a circuit module 100C according to this embodiment, a conductive shield 5C covers the outer surface of a sealing layer 4C, i.e., a second surface 42C and a first sealing area 411C and second sealing area 412C of a first surface 41C, similar to the first embodiment. However, the circuit module 100C is different from the first embodiment in that a first shield portion 51C is formed with a substantially uniform thickness.

Specifically, as shown in FIG. 11, the first shield portion 51C of the conductive shield 5C has a thickness D3 that is substantially uniform on the first sealing area 411C and the second sealing area 412C. Specifically, the first shield portion 51C is formed to have a shape that resembles the first surface 41C of the sealing layer 4C. The thickness D3 is not particularly limited, but can be set to be smaller than the thickness D1 of the first shield area 511 described in the first embodiment.

It is possible to produce the circuit module 100C according to this embodiment in the same way as in the first embodiment. Specifically, the method of producing the circuit module according to this embodiment includes a process of preparing an aggregate substrate, a process of mounting an electronic component, a process of forming a sealing layer, a half-cut process, a process of forming a conductive shield, and a cutting process. The producing method according to this embodiment is different from the first embodiment only in the process of forming the conductive shield.

In the process of forming the conductive shield according to this embodiment, by setting the amount of applying or filling a conductive resin to be smaller than that in the first embodiment, for example, it is possible to form the conductive shield so as to resemble the first surface 41C of the sealing layer 4C. The specific forming method is not particularly limited. For example, a molding method using a mold, a potting molding method using no mold, or the like can be applied. Alternatively, after a liquid or paste sealing resin material is applied to the sealing layer 4C by a spin coating method or a screen printing method, the resultant product may be cured by heat treatment.

According to this embodiment, it is also possible to reduce the parasitic capacitance between the conductive shield and the electronic component while regulating the thickness of the entire circuit module 100C.

### Modified Example

FIG. 12 is a schematic cross-sectional view showing a circuit module according to a modified example of this embodiment, which corresponds to the cross-sectional view shown in FIG. 4.

In a circuit module 100D according to this modified example, a conductive shield 5D covers a second surface 42D of a sealing layer 4D and a first sealing area 411D of a first surface 41D, and does not cover a second sealing area 412D. Specifically, the conductive shield 5D has an opening 513D exposing the second sealing area 412D, similar to the second embodiment.

The method of producing the circuit module 100D according to this modified example includes a process of removing the conductive shield on the second sealing area 412D by polishing in addition to the same processes as those in this embodiment. The method of polishing is not particularly limited, and it is possible to polish the area on the second sealing area 412D by dry polishing or the like. Accordingly, it is possible to form the circuit module 100D having a configuration as shown in FIG. 12.

In this embodiment, because a conductive resin film on the second sealing area 412D is formed to project in the process of applying or filling a conductive resin (see FIG. 11), it is possible to easily polish only the projected area.

Also according to this modified example, it is possible to reduce the parasitic capacitance (capacitive coupling) between the conductive shield and the electronic component while regulating the thickness of the entire circuit module 100D.

### Fourth Embodiment

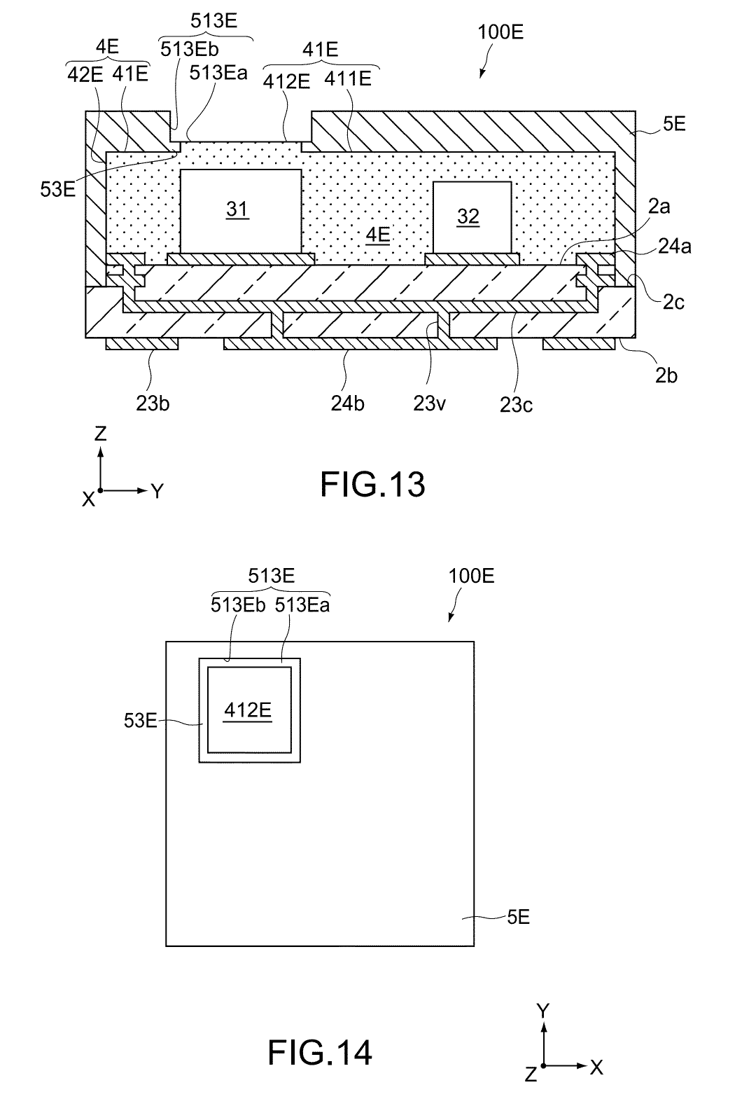

FIGS. 13 and 14 are each a diagram showing a circuit module according to a fourth embodiment of the present disclosure. FIG. 13 is a schematic cross-sectional view corresponding to the cross-sectional view shown in FIG. 4, and FIG. 14 is a plan view. Hereinafter, the configuration different from those of the first embodiment and the second embodiment will be mainly described, and the same configuration as those according to the above-mentioned embodiments will be denoted by the same reference symbols and a description thereof will be omitted or simplified.

In a circuit module 100E according to this embedment, a conductive shield 5E has an opening 513E that exposes a second sealing area 412E, similar to the second embodiment. In this embodiment, the opening 513E has a bottom surface 513Ea that exposes the second sealing area 412E and a wall surface 513Eb from which the conductive shield 5E is exposed.

The conductive shield 5E according to this embodiment has an edge portion 53E formed around the exposed second sealing area 412E, the edge portion 53E being exposed from the bottom surface 513Ea of the opening 513E. The edge portion 53E is configured to rim the second sealing area 412E when it is viewed from above the Z-axis direction (see FIG. 14). Accordingly, the conductive shield 5E is configured to have an uneven surface having the edge portion 53E and an area exposed from the wall surface 512Eb of the opening 513E.

Moreover, the shape of the opening 513E is not particularly limited. For example, as shown in FIG. 14, the bottom surface 513Ea may be configured to have a rectangular shape or a circular shape. Alternatively, the bottom surface 513Ea may be configured to have a curved surface in which the bottom surface 513Ea and the wall surface 513Eb are connected to each other.

The method of producing the circuit module according to this embodiment includes a process of preparing an aggregate substrate, a process of mounting an electronic component, a process of forming a sealing layer, a half-cut process, a process of forming a conductive shield, a process of removing a part of the conductive shield, and a cutting process.

The process of forming the conductive shield can be performed in the same way as the process of forming the conductive shield according to the first embodiment. Specifically, with reference to FIG. 8A, in this embodiment, the conductive shield is formed by applying or filling a conductive resin or conductive paint to/on the surface of a sealing layer 4E and to/in the cut groove. It should be noted that at this time, a conductive resin or the like having a sufficient thickness is filled or applied also on/to the second sealing area 412E.

Next, by forming a desired opening in the upper surface of the conductive shield, an area on the second sealing area 412E of the sealing layer 4E in the conductive shield is removed. Here, the opening may have a depth with which the opening reaches the second sealing area 412E and does not reach the surface of the first sealing area 411E. Moreover, the size of the opening seen in a plan view from above the Z-axis direction (hereinafter, also simply referred to as “in a plan view”) may be larger than that of the second sealing area 412E. Accordingly, the opening 513E having the bottom surface 513Ea and the wall surface 513Eb that expose the second sealing area 412E and the edge portion 53E is formed. For removing the conductive shield, machine processing such as grinding processing and cutting processing can be applied. Other than that, it is possible to apply laser processing, an etching method, or the like.

Then, by performing the cutting process similar to the first embodiment, it is possible to form the circuit module 100E shown in FIG. 13E. Also according to this embodiment, it is possible to prevent the parasitic capacitance (capacitive coupling) between the electronic component 31 and the conductive shield 5E from being generated while reducing the entire circuit module in size.

Moreover, because the opening 513E can be formed by machine processing such as grinding, it is possible to easily and reliably expose the second sealing area 412E.

Furthermore, in the circuit module 100E according to this embodiment, the depth of the opening 513E can be determined by confirming the second sealing area 412E and the edge portion 53E from above the Z-axis direction. Therefore, it is possible to easily identify an irregular or defective product. Specifically, in the case where it is difficult to confirm the second sealing area 412E (sealing layer 4E) when it is viewed from above the Z-axis direction, it is possible to determine that the depth of the opening 513E is smaller than the desired depth. On the other hand, in the case where it is possible to confirm the second sealing area 412E but not the edge portion 53E, it is possible to determine that the size of the opening 513E in a plan view is not sufficient or the depth of the opening 513E is larger than the surface of the first sealing area 411E. For example, in the case where the opening 513E has a large depth, there is a possibility that the electronic component 31 is damaged when the opening 513E is formed or the electronic component 31 is easily affected by the outside. Accordingly, it is possible to determine that the product is a defective product.

As described above, in an inspection process prior to shipment, for example, it is possible to easily identify a defective product by confirming the edge portion 53E from above the Z-axis direction, and thus to improve the inspection efficiency.

### Modified Example

The circuit module 100E according to this embodiment can be produced by the following way in addition to the above-mentioned producing method. Specifically, a half-cut process, a process of forming a first shield layer, a process of forming a second shield layer, and a cutting process may be included.

The first shield layer has a configuration that covers the second surface 42E of the sealing layer 4E and the first sealing area 411E of the first surface 41E and does not cover the second sealing area 412E, similar to the conductive shield 5B shown in FIG. 10 according to the second embodiment. In the process of forming the first shield layer, first, a conductive resin or conductive paint is applied or filled to/on the surface of the sealing layer 4E and to/in the cut groove, similar to the process of forming the conductive shield according to the first embodiment. Then, the area on the second sealing area 412E of the sealing layer 4E in the conductive shield is removed by polishing, similar to the second embodiment.

Next, the second shield layer is formed on the first shield layer, and has the opening 513E. In the process of forming the second shield layer, a mask that covers the second sealing area 412 of the first shield layer is disposed, and a conductive resin or the like is applied or filled via the mask, for example.

According to this modified example, because the second sealing area 412E can be exposed before the opening 513E is formed using a mask, it is possible to enhance the controllability of the shape of the opening 513E. Therefore, the electronic component 31 can be reliably covered by the sealing layer 4E, and it is possible to prevent a problem from occurring.

Although embodiments of the present disclosure have been described, the present disclosure is not limited to the above-mentioned embodiments and various modifications can be made based on the technical ideas of the present disclosure.

For example, in the above-mentioned embodiments, although the second sealing area has been described to be provided opposed to the electronic component, it is not limited thereto. For example, the second sealing area may be provided in an area that is not opposed to the electronic component. By forming a part of the sealing layer being a dielectric with a large thickness, it is possible to reduce electrical interference among electronic components due to the conductive shield and to prevent a problem in each electronic component on the wiring substrate from occurring.

For example, in the above-mentioned embodiments, the method of forming the second sealing layer via the mask after the first sealing layer is formed has been described as a method of forming a sealing layer, but it is not limited thereto. For example, an etching method can be applied, or laser processing or the like may be applied.

Moreover, the method of forming the opening in the conductive shield has been described to include polishing the upper surface of the conductive shield, but it is not limited thereto. For example, an etching method can be applied, or laser processing may be applied. In the present disclosure, because a part of the sealing layer is formed to have a large thickness, it is possible to reduce the possibility that the electronic component is damaged by laser processing.

Furthermore, in the above-mentioned embodiments, the example in which the wiring substrate 2 includes a print wiring substrate has been described. However, the wiring substrate 2 is not limited thereto, and may include a semiconductor substrate such as a silicon substrate. Moreover, the electronic component 3 may include various actuators such as MEMS (Micro Electro Mechanical System) components.

The present disclosure contains subject matter related to that disclosed in Japanese Priority Patent Application JP 2013-144579 filed in the Japan Patent Office on Jul. 10, 2013, the entire content of which is hereby incorporated by reference.

What is claimed is:

1. A circuit module, comprising:
a wiring substrate having a mount surface;
an electronic component mounted on the mount surface;
a sealing layer that is formed of an insulating material, covers the electronic component, and has a first surface and a second surface, the first surface being opposite to the mount surface and having a first sealing area and a second sealing area, the second sealing area projecting from the first sealing area to an opposite side of the mount surface, the second surface being connected to the mount surface and the first surface; and
a conductive shield covering at least the second surface and the first sealing area of the first surface.

2. The circuit module according to claim 1, wherein the second sealing area is provided opposite to the electronic component.

3. The circuit module according to claim 1, wherein the conductive shield further covers the second sealing area of the first surface.

4. The circuit module according to claim 3, wherein the conductive shield has a first shield portion that covers the first surface and has a first shield area and a second shield area, the first shield area being formed on the first sealing area with a first thickness, the second shield area being formed on the second sealing area with a second thickness smaller than the first thickness, and
a second shield portion that covers the second surface and is connected to the mount surface.

5. The circuit module according to claim 1, wherein the conductive shield has an opening exposing the second sealing area.

6. The circuit module according to claim 5, wherein the opening has a bottom surface exposing the second sealing area, and
the conductive shield further has an edge portion formed around the exposed second sealing area, the edge portion being exposed from the bottom surface of the opening.

7. The circuit module according to claim 1, wherein the wiring substrate includes a ground terminal electrically connected to the conductive shield.

8. A method of producing a circuit module, comprising:
preparing a wiring substrate having a mount surface on which an electronic component is mounted;
forming, on the mount surface, a sealing layer that is formed of an insulating material, covers the electronic component, and has a first surface and a second surface, the first surface being opposite to the mount surface and having a first sealing area and a second sealing area, the second sealing area projecting from the first sealing area to an opposite side of the mount surface, the second surface being connected to the mount surface and the first surface; and
forming a conductive shield covering an outer surface of the sealing layer.

9. The method of producing a circuit module according to claim 8, wherein the forming of the sealing layer includes
forming a first sealing layer covering the electronic component,
disposing, on the first sealing layer, a mask having an opening in an area corresponding to the second sealing area, and
forming, on the first sealing layer, a second sealing layer via the opening of the mask.

10. The method of producing a circuit module according to claim 8, further comprising removing the conductive shield on the second sealing area.
